(19) United States
(12) Patent Application Publication
(10) Pub. No.: US 2023/0389229 A1
(43) Pub. Date: Nov. 30, 2023

(54) Circuit Board Arrangement

(71) Applicant: Rolls-Royce Deutschland Ltd & Co KG, Blankenfelde-Mahlow (DE)

(72) Inventors: Stanley BUCHERT, Herzogenaurach (DE); Uwe WALTRICH, Forchheim (DE)

(21) Appl. No.: 18/203,609

(22) Filed: May 30, 2023

(30) Foreign Application Priority Data
May 31, 2022 (DE) 10 2022 113 642.6

(51) Int. Cl. H05K 7/20

(52) U.S. Cl. CPC H05K 7/20272; H05K 7/20409; H05K 2201/066

(57) ABSTRACT

A circuit board arrangement includes a circuit board that has an upper side and an underside, at least one electrical component that is arranged on the underside of the circuit board, and a heat sink that has a cavity, into which the electrical component projects. In this case, the circuit board lies on the cavity and covers the cavity. The cavity of the heat sink is sealed such that neither particles nor a fluid may escape from or enter the cavity between the circuit board and the heat sink.

This application claims the benefit of German Patent Application No. DE 10 2022 113 642.6, filed on May 31, 2022, which is hereby incorporated by reference in its entirety.

### BACKGROUND

The present embodiments relate to a circuit board arrangement.

The prior art includes the practice of cooling circuit board-based power electronics assemblies using a heat sink, where the components to be cooled are typically configured as surface-mounted (SMD) components (“surface-mounted device”) or in through-hole assembly (“through-hole technology” (THT)) and are seated on the underside of a circuit board. The thermal connection of the components to be cooled to the heat sink may be accomplished using a heat-conducting material, also referred to as a thermal interface material (TIM), which compensates for height tolerances and roughness and thereby avoids or at least considerably reduces the formation of a gap between the component to be cooled and the heat sink.

In order to provide a high thermal conductivity of the heat-conducting material used, there is a known practice of using paste systems with a high content of electrically conductive particles as the heat-conducting material. Other known heat-conducting materials are electrically conductive graphite foils and silicone-based heat-conducting foils.

However, there is the problem that the electrically conductive particles used in paste systems are typically not firmly bonded to the paste material, and therefore electrically conductive particles may be released over the time of use and depending on the conditions of use. Electrically conductive particles may be released from graphite foils by abrasion. Such electrically conductive particles form foreign particles in the power electronics assembly and may lead to short circuits. If silicone-based heat-conducting foils are used, the problem may arise that gas is released by silicone and isolates electrical contacts in an undesirable manner.

A further problem consists in that each heat-conducting material used represents an additional thermal resistance with limited thermal conductivity. Accordingly, there is less than optimum dissipation of waste heat from the component to be cooled to the heat sink. This provides that the relevant parameters of the component to be cooled cannot be set to the optimum values. The maximum size of the power dissipation and the maximum temperature of the component are the decisive parameters.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a circuit board arrangement that is suitable for improving the cooling of electrical components by a heat sink and/or operational reliability is provided.

In a first aspect of the present embodiments, a circuit board arrangement includes a circuit board with an upper side and an underside, at least one electrical component that is arranged on the underside of the circuit board, and a heat sink with a cavity, into which the electrical component projects. In this case, the circuit board lies on the cavity and covers the cavity.

It is provided that the cavity of the heat sink is sealed such that neither particles nor a fluid may escape from or enter the cavity between the circuit board and the heat sink.

The solution according to the present embodiments is based on the concept of sealing the cavity in the heat sink, in which the electrical component to be cooled is located, with respect to particles, gases and liquids. This prevents foreign substances due to abrasion or outgassing of heat-conducting materials from being able to escape from the cavity and cause damage (e.g., due to short circuits or the isolation of electrical contacts). By avoiding such risks, increased reliability and operational reliability are provided, which enable the use of thermally and electrically conductive heat-conducting materials with a high proportion of electrically conductive particles. This thus improves heat transfer between the component to be cooled and the heat sink. If silicone-based heat-conducting materials are used, the disadvantages associated with outgassing of silicone are avoided.

A further advantage associated with the present embodiments includes that the use of a sealed cavity makes it possible to employ liquid cooling for cooling the electrical component, as is the case in refinements of the present embodiments. This opens up the possibility of completely dispensing with the use of heat-conducting materials for the thermal connection of the component to be cooled to the heat sink and, instead, of implementing more effective liquid cooling with a cooling medium.

Attention is drawn to the fact that, for the purposes of the present embodiments, the side of the circuit board on which an electrical component to be cooled is arranged is always referred to as the underside of the circuit board. This is typically the side of the circuit board that is closer to the ground with respect to the vertical perpendicular direction. However, the circuit board and the electrical component to be cooled may also be arranged in an inverted or vertical manner and accordingly point upwards or to the side. In this case, for the purposes of the present embodiments, the electrical component to be cooled is likewise arranged on the underside of the circuit board and adjoins the heat sink with its underside.

Attention is further drawn to the fact that the cavity is sealed on its upper side in a natural way by the circuit board. Thus, a circuit board consists of a material through which particles or a fluid cannot pass. For the complete sealing of the cavity, a seal is to be achieved between the heat sink and the circuit board laterally adjacent to the cavity.

With regard to the feature that neither particles nor a fluid may escape from or enter the cavity between the circuit board and the heat sink, a fluid is to be able to enter and leave the cavity at some other point (e.g., in the region of the heat sink, such as in the case of liquid cooling) in order to provide a flow of a cooling medium.

One refinement of the present embodiments provides that the circuit board forms, adjacent to the cavity, a bearing surface that rests on the heat sink, where a region between the heat sink and the bearing surface of the circuit board is sealed. The sealing is accomplished, for example, by a sealing ring that is arranged between the circuit board and the heat sink.

For this purpose, one embodiment provides for the sealing ring to extend between the bearing surface of the circuit board and the heat sink. The sealing ring is arranged, for example, in a groove of the heat sink. The groove extends adjacent to the cavity in the heat sink and is formed circumferentially around the cavity. The groove may be of circular or polygonal design, for example. Alternatively, the groove may be formed in the circuit board.

A further refinement provides that the circuit board arrangement includes screw connections that are provided and configured to press the circuit board against the heat sink counter to the elastic force of the sealing ring. A very effective seal of the cavity is thus provided. In this case, the non-positive engagement for sealing is provided by the screw connections.

As already noted, one refinement of the present embodiments provides cooling, which includes a cooling medium and device(s) and/or structure configured to produce a flow of the cooling medium through the sealed cavity. According to this refinement, the sealed cavity is used to implement liquid cooling with a liquid cooling medium. In this case, a flow of the cooling medium impinges directly on the component to be cooled. This variant of the present embodiments avoids the use of heat-conducting materials and thereby reduces the thermal resistance between the electrical components to be cooled and the heat sink or cooling medium.

A further advantage associated with this variant of the present embodiments consists in that reduced demands are made on the soldering process in which the electrical component is fastened and contacted on the underside of the circuit board. This is because the liquid cooling provides that possible tilting of the electrical components to be cooled and increased height tolerances between individual electrical components are no longer relevant with regard to the thermal cooling of the electrical components. As a result, reduced mechanical tolerance requirements may be accepted for the entire circuit board structure.

One refinement provides that at least one turbulence generator is integrated into the cavity. The turbulence generator is provided and configured to intensify cooling of the electrical component by the cooling medium by directing the cooling medium in the cavity against the underside of the electrical component. For this purpose, cooling channels are provided in the turbulence generator. The cooling channels guide the cooling medium vertically upwards in a turbulent manner.

A further refinement provides that the device(s) and/or structure for producing a flow includes flow channels that are formed in the heat sink. Further, the device(s) and/or structure for producing a flow in refinements includes at least one propeller that is arranged, for example, in the flow channels or upstream or downstream of the flow channels, and provides a liquid flow of the cooling medium. Alternatively or additionally, the liquid flow may be provided by a predetermined pressure gradient.

A further refinement provides that the underside of the electrical component has a lower metallization layer that provides a thermal interface. The metallization layer may consist of a material having a high thermal conductivity (e.g., a thermal conductivity greater than 200 W/(mK), greater than 300 W/(mK), or greater than 400 W/(mK)). As a result, effective cooling of the electrical component is provided both in the case of liquid cooling and in the case of cooling using a heat-conducting material.

In a further refinement of the present embodiments, all the electrical contact connections on the underside of the circuit board are provided with insulation in a region of the cavity. Such insulation is provided by a coating, for example. The insulation prevents the penetration of particles, gases, or liquid, and thus impairment of the electrical connection. In the case of liquid cooling, the underside of the circuit board is configured, at least in the region of the cavity, to be able to receive a flow of a cooling medium without impairment.

Further, the electrical component may be arranged in an insulating (e.g., moisture-insulating) sheath (e.g., an encapsulating material made of plastic) in order to provide protection of the electrical component from particles, gases, and liquids.

If liquid cooling is not implemented, one refinement of the present embodiments provides that the underside of the electrical component is thermally connected to the heat sink via a thermal interface material or heat-conducting material. The thermal interface material is configured, for example, as a heat-conducting mat or as a heat-conducting paste.

Generally, the electrical components in refinements of the present embodiments may be semiconductor components (e.g., power semiconductors such as power MOSFETs or IGBT components). These are, for example, power semiconductors of an inverter or, in general, of a power converter that is provided for the operation of an electric motor.

In principle, the electrical component may be any electrical component or any electrical assembly. One refinement provides that the electrical components each have: a ceramic circuit carrier that has an insulating ceramic layer and a metallization layer arranged on the upper side of the ceramic layer; an electrical component that is arranged on the upper side of the metallization layer and is electrically connected thereto; an upper side of the electrical component that is arranged on the underside of the circuit board (where the upper side of the electrical component forms electrical contacts that are provided and configured to come into contact with associated electrical contacts of the circuit board); and an underside of the electrical component.

As explained, the thermal coupling of the electrical component to the heat sink may be accomplished via a heat-conducting material or alternatively via a cooling medium of a liquid cooling system.

Further, a lower metallization layer that forms a thermal interface of the electrical component may be arranged on the underside of the ceramic layer.

The electrical component is, for example, the actual power semiconductor such as, for example, a power MOSFET or an IGBT component. The ceramic circuit carrier serves for electrical insulation of the electrical component from the heat sink and at the same time for thermal connection to the heat sink. In this case, the ceramic circuit carrier, together with the semiconductor component and a sheath (e.g., made of encapsulating material), form an electrical module that may be connected to the circuit board (e.g., that may represent a carrier board) via contacts formed on a surface of the electrical module. Such an electrical module is also referred to as a prepackaged module.

In a further aspect of the present embodiments, a method for cooling an electrical component is provided. The method includes arranging an electrical component that is arranged on an underside of a circuit board, in a sealed cavity of a heat sink, and directing a cooling medium through the sealed cavity.

The method according to the present embodiments is based on the concept of making possible the circulation of a cooling medium in the cavity by providing a sealed cavity and thereby achieving the cooling of an electrical component to be cooled arranged in the cavity in an effective manner.

In one refinement, the cooling medium is directed turbulently upwards against the underside of the electrical component in the cavity by a turbulence generator in order to increase the effectiveness of cooling.

### BRIEF DESCRIPTION OF THE DRAWINGS

FIG. 1 shows an embodiment of a circuit board arrangement;

FIG. 2 shows a further embodiment of a circuit board arrangement;

FIG. 3 schematically shows a heat sink of a circuit board arrangement according to FIG. 2, in which production of a cooling fluid flow in a sealed cavity is integrated into the heat sink;

FIG. 4 shows a circuit board arrangement having a circuit board, electrical components, and a heat sink;

FIG. 5 shows an embodiment of an electrical component in the form of a prepackaged module; and

FIG. 6 shows a flow diagram of method acts of one embodiment of a method for cooling an electrical component.

### DETAILED DESCRIPTION

For a better understanding of the background of the present embodiments, a circuit board arrangement that is not according to the present embodiments is first described with reference to FIG. 4.

FIG. 4 shows a circuit board arrangement that includes a circuit board 1 and a heat sink 3. The circuit board 1 may include a number of circuit board layers (not shown separately) that are arranged one above the other. In this case, an uppermost circuit board layer forms an upper side 11 of the circuit board 1 and a lowermost circuit board layer forms an underside 12 of the circuit board 1.

Electrical components 2 are arranged on the underside 12 of the circuit board 1. The connection to the circuit board 1 is accomplished, for example, by surface mounting or through-hole mounting. In addition, electrical components may also be arranged on the upper side 11 of the circuit board 1. The components 2 arranged on the underside 12 are active components (e.g., components or assemblies of the power electronics) that require cooling by the heat sink 3. For this purpose, the heat sink 3 has a cavity or recess 4, into which the components 2 to be cooled project. In this case, the circuit board 1 covers the cavity 4 on the upper side.

A heat-conducting material 7, which is also referred to as a thermal interface material, is arranged on a bottom surface 32 of the heat sink 3 in the cavity 4, between the components 2 to be cooled and the heat sink 3. This material is, for example, a heat-conducting mat or a heat-conducting paste. Using the heat-conducting material 7, a gap is avoided between the respective component 2 and the heat sink 3, which would impair the thermal connection of the component 2 to the heat sink 3.

The circuit board 1 is screwed to the heat sink 3 using screws 5. The screws 5 are screwed into through-holes 15 that extend from the circuit board 1 into the heat sink 3.

The heat sink 3 may have numerous configurations. For example, the heat sink 3 consists of a metal such as, for example, aluminum or an aluminum alloy and has cooling surfaces (not shown separately). The heat sink 3 is, for example, an active heat sink that is actively cooled by a fan (not shown) or by a liquid cooling system (not shown). Alternatively, the heat sink 3 is configured as a passive heat sink.

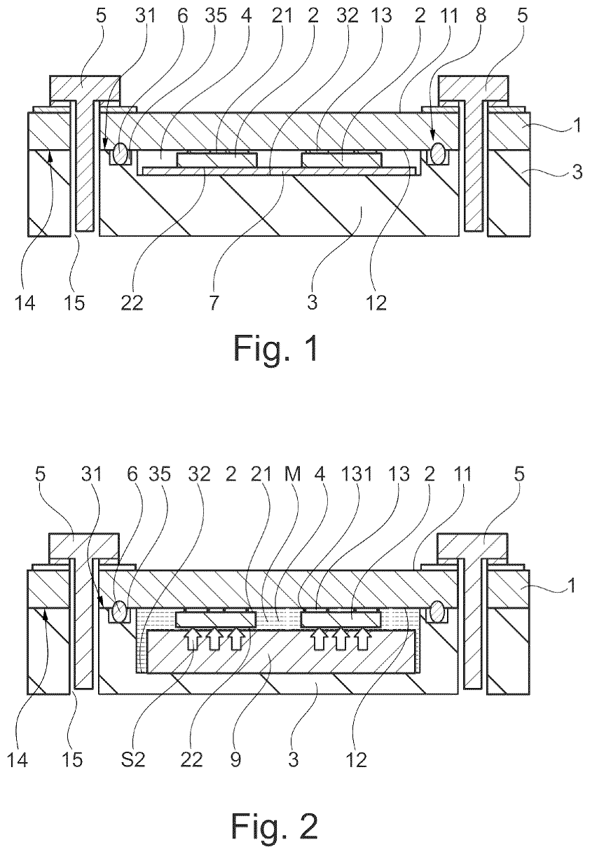

FIG. 1 shows a first exemplary embodiment of a circuit board arrangement. The circuit board arrangement includes a circuit board 1, a plurality of electrical components 2, and a heat sink 3. The circuit board 1 has an upper side 11 and an underside 12. The plurality of electrical components 2 each have an upper side 21 and an underside 22. On the upper sides 21, the plurality of electrical components 2 are arranged on the underside 12 of the circuit board 1, forming electrical contacts 13. The heat sink 3 further includes a cavity 4 that, in the illustrated exemplary embodiment, though not necessarily, is formed in a rectangular shape in the heat sink 3. The electrical components 2 may project into the cavity 4. A thermal interface material 7 is arranged between the underside 22 of the electrical component 2 and the heat sink 3.

To this extent, the structure is the same as in the circuit board arrangement of FIG. 4, and therefore reference is additionally made to the explanations relating thereto.

In contrast to FIG. 4, the cavity 4 of the circuit board arrangement of FIG. 1 is sealed such that neither particles nor a fluid may escape from or enter the cavity 4 between the circuit board 1 and the heat sink 3. For this purpose, it is provided that the circuit board 1 forms, at the edge of the cavity 4, a bearing surface 14 that rests in a sealed manner on the upper side 31 of the heat sink 3 via a sealing ring 6. A region 8 between the heat sink 3 and the bearing surface 14 of the circuit board is sealed. In this case, the sealing ring 6 is arranged in a groove 35 that is formed circumferentially in the heat sink 3 adjacent to the cavity 4. The sealing ring 6 consists of an elastomer, for example.

The non-positive engagement for sealing is provided by screws 5 that are screwed into through-holes 15 that extend from the circuit board 1 into the heat sink 3. In this case, the screws 5 rest, for example, on the upper side 11 of the circuit board 1 via a washer and a metallization. The screws 5 provide a pressure force with which the circuit board 1 is pressed against the heat sink 3 counter to the elastic force of the sealing ring 6. The cavity 4 is sealed by the elastic deformation of the sealing ring 6.

As a result of the pressure force provided, the components 2 to be cooled, which are arranged on the underside 12 of the circuit board 1, are further pressed against the surface of the heat sink 3 via the heat-conducting material 7 in order to provide good heat transfer.

Providing a sealed cavity 4 prevents electrically conductive particles released from the heat-conducting material 7 and/or foreign particles and/or outgases from escaping from the cavity 4.

FIG. 2 shows an alternative exemplary embodiment of a circuit board arrangement, which differs from the exemplary embodiment of FIG. 1 by the type of cooling. With regard to the provision of a sealed cavity 4 using a sealing ring 6, attention is drawn to the explanations of FIG. 1.

In the exemplary embodiment of FIG. 2, the sealed cavity 4 is used to implement liquid cooling. A thermal interface material is not provided. The liquid cooling includes a cooling medium M and device(s) and/or structure for producing a flow of the cooling medium M through the sealed cavity 4. The cooling medium M completely fills the space of the cavity 4. All the electrical contacts are insulated from the cooling medium M. For this purpose, the electrical contacts 13 between the electrical component 2 and the circuit board 1 are coated with a schematically illustrated coating 131. The circuit board 1 is also configured to be able to receive a direct flow of the cooling medium M on its underside 12 without limitation of its function.

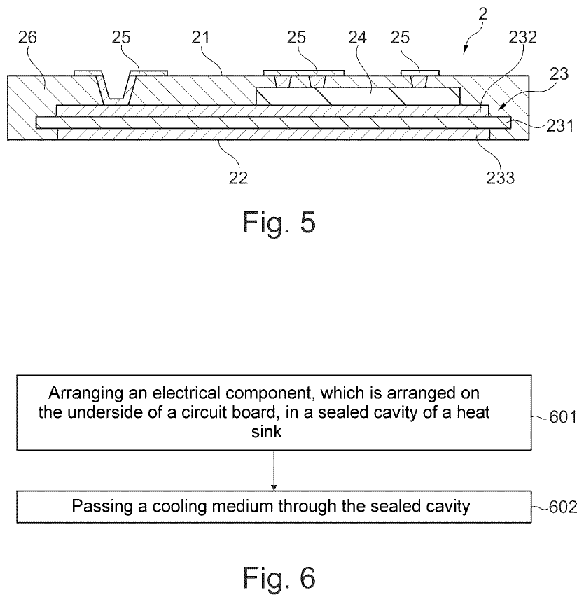

To improve the heat transfer between the electrical component 2 to be cooled and the cooling medium M, turbulence generators 9 are arranged in the cavity 4 on the bottom surface 32 of the heat sink 3. The turbulence generators 9 impart a vertical directional component S2 on the flow of the cooling medium M in the cavity 4, resulting in direct impingement of a turbulent flow on the underside 22 of the component 2 to be cooled. This represents a thermal interface of the electrical component 2 and, for this purpose, in refinements, includes a metallization layer (as is explained by way of example with reference to FIG. 5).

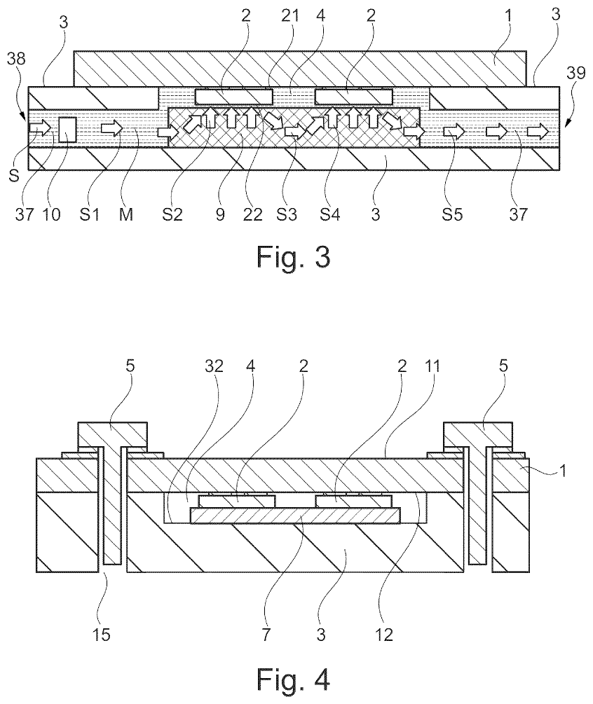

This functional mechanism is explained in more detail with reference to FIG. 3, where FIG. 3 is schematic insofar as the sealing ring 6, the groove 35, and the screws 5 are not shown separately for the sake of greater clarity, but are present just as in FIG. 2.

According to this, the device(s) and/or structure for producing a flow of the cooling medium M through the sealed cavity 4 includes flow channels 37 that are formed in the heat sink 3 and provide a coolant inlet 38 and a coolant outlet 39. In this case, a flow generator such as, for example, a propeller 10 may be integrated into the flow channels 37. This is, however, to be understood merely as an example. Alternatively, it is also possible for a propeller 10 to be arranged upstream of the coolant inlet 38 and/or downstream of the coolant outlet 39. Further, embodiment variants that do not require a propeller and are based on a predetermined pressure difference that produces a flow S of the cooling medium M may be provided.

FIG. 3 also shows the turbulence generator 9, which guides the cooling medium M below the electrical components 2 in a partially turbulent manner against the underside 22 of the electrical components 2. This is illustrated in FIG. 3 by the flow direction of the flow S of the cooling medium M. The flow S has a horizontal orientation at the coolant inlet 38 and downstream of the propeller 10 as flow S1. In the turbulence generator 9, part of the flow is deflected vertically upwards as flow S2, with the result that the flow S2 flows against the underside 22 of the electrical component 2. Between two electrical components 2, the flow is again guided horizontally as flow S3 in order to flow turbulently against the underside of the electrical component 2 under the next electrical component 2 as flow S4, again with a vertical component. Towards the coolant outlet 39, the flow is once again substantially horizontal as flow S5.

Such turbulence generators for direct liquid cooling are known in principle and are sold by Danfoss Silicon Power GmbH, for example.

The cooling medium M is, for example, an oil.

The refinements in FIGS. 2 and 3 for producing liquid cooling should be understood merely as illustrative. Numerous modifications with regard to the formation of the flow channels and the generation of a flow are possible. At the same time, a sealed cavity 4 is always provided, in which no cooling liquid may escape from the cavity 4 between the circuit board 1 and the heat sink 3.

The electrical components 2 of FIGS. 1 to 3 may be configured in exemplary embodiments according to FIG. 5. According to this, the electrical component 2 includes a ceramic circuit carrier 23, an electrical component 24, and electrical contacts 25. The electrical component 24 is a power semiconductor, for example.

The ceramic circuit carrier 23 includes an insulating ceramic layer 231, an upper metallization layer 232 arranged on the upper side of the ceramic layer 231, and an optional lower metallization layer 233 arranged on the underside of the ceramic layer 231. The electrical component 24 is arranged on the upper metallization layer 232. The ceramic circuit carrier 23 and the electrical component 24 are arranged in a substrate 26 that defines the external dimensions of the electrical component 2. The substrate 26 is, for example, an encapsulating compound, in which the ceramic circuit carrier 23 and the electrical component 24 are embedded, or a circuit board, in which the ceramic circuit carrier 23 and the electrical component 24 are embedded. In this case, the substrate 26 provides insulation for the electrical component 2. For example, provision may be made, in the case of a circuit board arrangement according to FIGS. 2 and 3, for the substrate 26 to provide insulation from a cooling fluid.

The substrate 26 includes an upper side 21, which also forms the upper side of the electrical component 2. An underside of the substrate 26 extends flush with the lower metallization layer 233. The underside of the substrate 26 and the lower metallization layer 233 form the underside 22 of the electrical component 2. Overall, the electrical component 2 is of cuboidal design.

The upper side 21 of the electrical component 2 has a plurality of electrical contacts 25 that serve to make contact with corresponding contacts of the circuit board 1 (see FIGS. 1 and 2). The electrical contacts 25 include through-connections to an underside potential and to upper side potentials of the electrical component 24. For example, the electrical contacts 25 provide a source terminal, a gate terminal, and a drain terminal of the electrical component 24.

According to the exemplary embodiment of FIG. 1, the electrical component 2 is connected to a heat sink via the metallization layer 233 and a heat-conducting mat. According to the exemplary embodiment of FIG. 2, the metallization layer 233 on the underside 22 of the electrical component 2 provides a thermal interface, which is cooled by a cooling medium of a liquid cooling system.

The ceramic circuit carrier 23 with the ceramic layer 231 serves for electrical insulation of the electrical component 24 arranged on the ceramic circuit carrier 23 from the heat sink and provides a thermal connection to the heat sink or cooling fluid. An electrical component 2 according to FIG. 5 is also referred to as a prepackaged module.

FIG. 6 shows method acts of a method for cooling an electrical component. According to act 601, an electrical component (e.g., an electrical component according to FIG. 5 that is arranged on the underside of a circuit board) is arranged in a sealed cavity of a heat sink. Providing a sealed cavity in the heat sink is a prerequisite here for the following act 602. In act 602, a cooling medium is passed through the sealed cavity. Liquid cooling of the electrical component 2 is thereby provided.

The invention is not restricted to the embodiments described above, and various modifications and improvements may be undertaken without departing from the concepts described here. Any of the features described may be used separately or in combination with any other features, to the extent that the features are not mutually exclusive. The disclosure extends to and includes all combinations and sub-combinations of one or a plurality of features that are described here. If ranges are defined, the ranges thus include all of the values within the ranges, as well as all of the partial ranges that lie within a range.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A circuit board arrangement comprising:
a circuit board that has an upper side and an underside;
at least one electrical component that is arranged on the underside of the circuit board; and
a heat sink that has a cavity, into which the at least one electrical component projects, wherein the circuit board lies on the cavity and covers the cavity,
wherein the cavity of the heat sink is sealed, such that neither particles nor a fluid is escapable from or enterable to the cavity between the circuit board and the heat sink.

2. The circuit board arrangement of claim 1, wherein the circuit board forms, adjacent to the cavity, a bearing surface that rests on the heat sink, and
wherein a region between the heat sink and the bearing surface of the circuit board is sealed.

3. The circuit board arrangement of claim 2, further comprising a sealing ring that is arranged between the circuit board and the heat sink.

4. The circuit board arrangement of claim 3, wherein the sealing ring extends between the bearing surface of the circuit board and the heat sink.

5. The circuit board arrangement of claim 3, wherein the sealing ring is arranged in a groove of the heat sink,
wherein the groove is formed in the heat sink adjacent to the cavity.

6. The circuit board arrangement of claim 3, further comprising screw connections that are configured to press the circuit board against the heat sink counter to an elastic force of the sealing ring.

7. The circuit board arrangement of claim 1, further comprising a cooling device that comprises a cooling medium and means for generating a flow of the cooling medium through the sealed cavity.

8. The circuit board arrangement of claim 7, further comprising at least one turbulence generator that is integrated into the cavity,
wherein the turbulence generator is configured to direct the cooling medium in the cavity against an underside of the at least one electrical component, such that cooling of the at least one electrical component is intensified by the cooling medium.

9. The circuit board arrangement of claim 8, wherein the turbulence generator is arranged in the cavity on a bottom surface of the heat sink.

10. The circuit board arrangement of claim 7, wherein the means for generating the flow of the cooling medium comprise flow channels that are formed in the heat sink.

11. The circuit board arrangement of claim 7, wherein the means for generating the flow of the cooling medium comprise a propeller.

12. The circuit board arrangement of claim 1, wherein an underside of the at least one electrical component has a lower metallization layer, which provides a thermal interface of the at least one electrical component.

13. The circuit board arrangement of claim 1, wherein all electrical contact connections on the underside of the circuit board are provided with insulation in a region of the cavity.

14. The circuit board arrangement of claim 1, wherein the at least one electrical component is provided with an insulating sheath.

15. The circuit board arrangement of claim 1, wherein an underside of the at least one electrical component is thermally connected to the heat sink via a thermal interface material.

16. The circuit board arrangement of claim 1, wherein the at least one electrical component comprises semiconductor components.

17. The circuit board arrangement of claim 12, wherein each electrical component of the at least one electrical component comprises:
a ceramic circuit carrier that has an insulating ceramic layer and an upper metallization layer arranged on an upper side of the insulating ceramic layer;
an electrical component that is arranged on an upper side of the upper metallization layer, the electrical component being electrically connected to the upper metallization layer;
an upper side of the respective electrical component, which is arranged on the underside of the circuit board; and
an underside of the respective electrical component.

18. The circuit board arrangement of claim 17, wherein the lower metallization layer is arranged on an underside of the insulating ceramic layer.

19. A method for cooling an electrical component, the method comprising:
arranging the electrical component, which is arranged on an underside of a circuit board, in a sealed cavity of a heat sink; and
directing a cooling medium through the sealed cavity.

20. The method of claim 19, wherein the cooling medium in the sealed cavity is directed turbulently upwards against an underside of the electrical component by a turbulence generator.
